(19) United States
(12) Patent Application Publication
(10) Pub. No.: US 2025/0324852 A1
(43) Pub. Date: Oct. 16, 2025

(54) DISPLAY PANEL, DISPLAY APPARATUS, AND FORMATION METHOD OF DISPLAY PANEL

(71) Applicants: Wuhan Tianma Micro-Electronics, Co., Ltd., Wuhan (CN); Wuhan Tianma Micro-Electronics Co., Ltd. Shanghai Branch, Shanghai (CN)

(72) Inventor: Wenxin JIANG, Wuhan (CN)

(21) Appl. No.: 18/784,364

(22) Filed: Jul. 25, 2024

(30) Foreign Application Priority Data
Apr. 11, 2024 (CN) 202410437329.3

(51) Int. Cl. H10K 59/122; H10K 59/12; H10K 59/40; H10K 59/80

(52) U.S. Cl. CPC H10K 59/122; H10K 59/1201; H10K 59/40; H10K 59/80521

(57) ABSTRACT

A display panel includes a substrate; a driving circuit layer on the substrate; first electrodes on the driving circuit layer; a pixel definition layer on a side of the first electrodes away from the substrate, where the pixel definition layer is patterned to form pixel definition regions, and the pixel definition regions correspondingly expose the first electrodes; a light-emitting functional layer formed on the first electrodes at the pixel definition regions; isolation columns on the pixel definition layer between adjacent pixel definition regions; and a common electrode. The common electrode includes second electrodes covering the light-emitting functional layer, suspension electrodes covering a top surface of the isolation columns, and touch-control electrodes covering the pixel definition layer on a side of the isolation columns away from the pixel definition region; and the second electrodes, the suspension electrodes and the touch-control electrodes are disconnected from each other.

### CROSS-REFERENCE TO RELATED APPLICATION

The present disclosure claims the priority of Chinese Patent Application No. 202410437329.8, filed on Apr. 11, 2024, the content of which is incorporated herein by reference in its entirety.

### TECHNICAL FIELD

The present disclosure generally relates to the field of display technology and, more particularly, relates to a display panel, a display apparatus, and a formation method of the display panel.

### BACKGROUND

Currently, the touch-control design of OLED (organic light-emitting diode) display panel mainly adopts TPOT (touch-control panel on TFE (thin film encapsulation)) structure, that is, touch-control structure formed on TFE (thin film encapsulation).

In the existing technology, the touch-control structure may be configured on TFE, and the common electrode of the display panel may be configured as entire cathode, which may result in relatively large parasitic capacitance formed between entire cathode of the display panel and the touch-control electrode in the touch-control structure and result in relatively large mutual interference between the display signal and the touch-control signal, thereby reducing product performance. Furthermore, forming the touch-control structure on TFE may also increase product process and extend production cycle.

### SUMMARY

One aspect of the present disclosure provides a display panel. The display panel includes a substrate; a driving circuit layer on the substrate; first electrodes on the driving circuit layer; a pixel definition layer on a side of the first electrodes away from the substrate, where the pixel definition layer is patterned to form pixel definition regions, and the pixel definition regions correspondingly expose the first electrodes; a light-emitting functional layer formed on the first electrodes at the pixel definition regions; isolation columns on the pixel definition layer between adjacent pixel definition regions; and a common electrode. The common electrode includes second electrodes covering the light-emitting functional layer, suspension electrodes covering a top surface of the isolation columns, and touch-control electrodes covering the pixel definition layer on a side of the isolation columns away from the pixel definition region; and the second electrodes, the suspension electrodes and the touch-control electrodes are disconnected from each other.

Another aspect of the present disclosure provides a display apparatus including a display panel. The display panel includes a substrate; a driving circuit layer on the substrate; first electrodes on the driving circuit layer; a pixel definition layer on a side of the first electrodes away from the substrate, where the pixel definition layer is patterned to form pixel definition regions, and the pixel definition regions correspondingly expose the first electrodes; a light-emitting functional layer formed on the first electrodes at the pixel definition regions; isolation columns on the pixel definition layer between adjacent pixel definition regions; and a common electrode. The common electrode includes second electrodes covering the light-emitting functional layer, suspension electrodes covering a top surface of the isolation columns, and touch-control electrodes covering the pixel definition layer on a side of the isolation columns away from the pixel definition region; and the second electrodes, the suspension electrodes and the touch-control electrodes are disconnected from each other.

Another aspect of the present disclosure provides a formation method of a display panel. The method includes forming a driving circuit layer on a substrate; forming first electrodes on the driving circuit layer; forming a pixel definition layer on a side of the first electrodes away from the substrate, where the pixel definition layer is patterned to form pixel definition regions, and the pixel definition regions correspondingly expose the first electrodes; forming isolation columns on the pixel definition layer between adjacent pixel definition regions; forming a light-emitting functional layer on the first electrodes at the pixel definition region; and forming a common electrode, where the common electrode includes second electrodes covering the light-emitting functional layer, suspension electrodes covering a top surface of the isolation columns, and touch-control electrodes covering the pixel definition layer on a side of the isolation columns away from the pixel definition region; and the second electrode, the suspension electrode and the touch-control electrode are disconnected from each other.

Other aspects of the present disclosure may be understood by those skilled in the art in light of the description, the claims, and the drawings of the present disclosure.

### BRIEF DESCRIPTION OF THE DRAWINGS

The accompanying drawings, which are incorporated into a part of the specification, illustrate embodiments of the present disclosure and together with the description to explain the principles of the present disclosure.

In order to clearly explain embodiments of the present disclosure or the technical solutions in the existing technology, the drawings required for describing embodiments or the existing technology are briefly introduced hereinafter. Obviously, the drawings in the following description are merely embodiments of the present disclosure. Other drawings may also be obtained by those skilled in the art without any creative work according to provided drawings.

FIG. 1 illustrates a cross-sectional view along an A-A′ direction in FIG. 2 according to various embodiments of the present disclosure.

FIG. 2 illustrates a top view of a display panel according to various embodiments of the present disclosure.

FIG. 3 illustrates a top view only corresponding to second electrodes shown in FIG. 2 according to various embodiments of the present disclosure.

FIG. 4 illustrates a top view only corresponding to suspension electrodes shown in FIG. 2 according to various embodiments of the present disclosure.

FIG. 5 illustrates a top view only corresponding touch-control electrodes shown in FIG. 2 according to various embodiments of the present disclosure.

FIG. 6 illustrates a cross-sectional view along a B-B′ direction in FIG. 7 according to various embodiments of the present disclosure.

FIG. 7 illustrates a top view of another display panel according to various embodiments of the present disclosure.

FIG. 8 illustrates a cross-sectional view along a C-C′ direction in FIG. 9 according to various embodiments of the present disclosure.

FIG. 9 illustrates a top view of another display panel according to various embodiments of the present disclosure.

FIG. 10 illustrates a film layer structural schematic of a display panel according to various embodiments of the present disclosure.

FIG. 11 illustrates another film layer structural schematic of a display panel according to various embodiments of the present disclosure.

FIG. 12 illustrates another film layer structural schematic of a display panel according to various embodiments of the present disclosure.

FIG. 13 illustrates another film layer structural schematic of a display panel according to various embodiments of the present disclosure.

FIG. 14 illustrates another film layer structural schematic of a display panel according to various embodiments of the present disclosure.

FIG. 15 illustrates another film layer structural schematic of a display panel according to various embodiments of the present disclosure.

FIG. 16 illustrates a structural schematic of a display apparatus according to various embodiments of the present disclosure.

FIG. 17 illustrates a flowchart of a formation method of a display panel according to various embodiments of the present disclosure.

FIG. 18 illustrates a schematic of a formation process of a display panel according to various embodiments of the present disclosure.

FIG. 19 illustrates another schematic of a formation process of a display panel according to various embodiments of the present disclosure.

### DETAILED DESCRIPTION

In order to clearly understand above-mentioned objectives, features and advantages of the present disclosure, the solutions of the present disclosure are further described hereinafter. It should be noted that embodiments of the present disclosure and the features in embodiments may be combined with each other if there is no conflict.

Specific details are described in the following description to facilitate thorough understanding of the present disclosure, but the disclosure may also be implemented otherwise than as described herein. Obviously, embodiments in the description are only some of embodiments of the present disclosure, but not all embodiments.

A display panel provided by embodiments of the present disclosure may divide a common electrode of the display panel into three parts by disposing isolation columns between adjacent pixel definition regions. Three parts may be respectively second electrodes (configured as display electrodes) disposed on a light-emitting functional layer, suspension electrodes covering the top surface of the isolation columns, and touch-control electrodes covering the pixel definition layer on the side of the isolation columns away from the pixel definition region. As a result, the common electrode of the display panel may be divided into display electrodes, suspension electrodes and touch-control electrodes that are disconnected from each other. Compared with the existing technology, the display panel provided by embodiments of the present disclosure may not need to dispose additional touch-control electrodes after the TFE is formed, which may be beneficial for simplifying process; and a part of the common electrode may be configured as touch-control electrodes of the display panel, which may be beneficial for reducing mutual interference between the display signal and the touch-control signal, thereby being beneficial for improving the product yield.

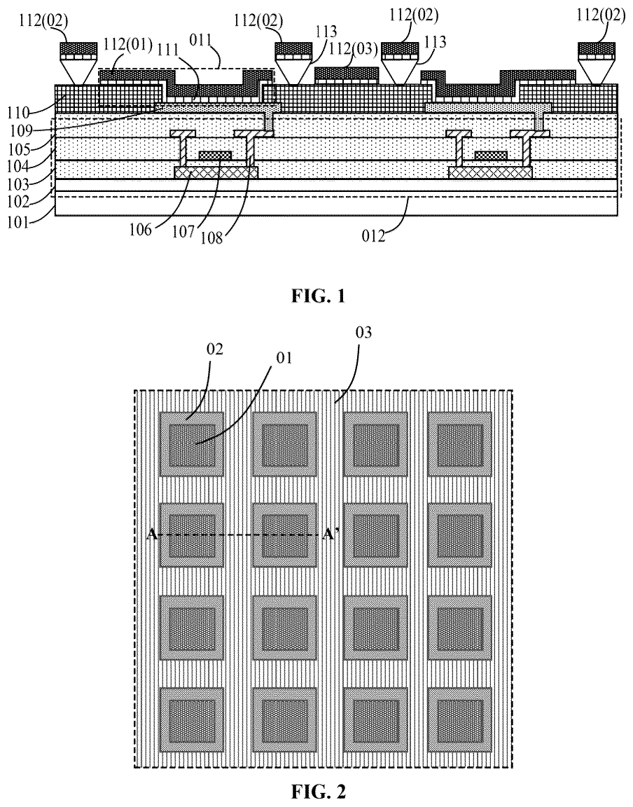

FIG. 1 illustrates a film layer structural schematic of a display panel according to various embodiments of the present disclosure. As shown in FIG. 1, the display panel may include a substrate 101, a driving circuit layer 012, first electrodes 109, a pixel definition layer 110, a light-emitting functional layer 111, isolation columns 113 and a common electrode 112.

For example, the driving circuit layer 012 may be on the substrate 101, the first electrode 109 may be on the driving circuit layer 012, and the pixel definition layer 110 may be on the side of the first electrode 109 away from the substrate 101.

The substrate 101 may be a glass substrate or a flexible substrate such as a PI (polyimide) substrate. The driving circuit layer 012 may be configured to drive the light-emitting functional layer 111 to emit light.

As shown in FIG. 1, the driving circuit layer 012 may include a buffer layer 102, a semiconductor active layer 106, a first insulating layer 103, a gate metal layer 107, a second insulating layer 104, a source and drain layer 108 and a third insulating layer 105. The semiconductor active layer 106 may be patterned to form a channel of a thin film transistor. The gate metal layer 107 may be patterned to form the gate electrode of the thin film transistor and the scan lines of a driving circuit. The source and drain layer 108 may be patterned to form the source electrode and the drain electrode of the thin film transistor and the data lines and power lines of the driving circuit. The third insulating layer 105 may cover the second insulating layer 104 and the source and drain layer 108, which may be configured to planarize the driving circuit layer 012 and provide a flat base for the preparation of the first electrode 109.

The pixel definition layer 110 may be formed with a pixel definition region 011. The pixel definition region 011 may correspondingly expose the first electrode 109, such that the light-emitting functional layer 111 corresponding to the pixel definition region 011 may be electrically connected to the first electrode 109. Exemplarily, the pixel definition layer 110 may be patterned through an exposure and development process to form the pixel definition region 011 as shown in FIG. 1.

For example, the light-emitting functional layer 111 may be formed on the first electrode 109 of the pixel definition region 011, and the first electrode 109 may be configured as the pixel electrode of the light-emitting functional layer 111; the isolation column 113 may be on the pixel definition layer 110 between adjacent pixel definition regions 011; the common electrode 112 may include the second electrode 01 covering the light-emitting functional layer 111, the suspension electrode 02 covering the top surface of the isolation column 113, and the touch-control electrode 03 covering the pixel definition layer 110 on the side of the isolation column 113 away from the pixel definition region 011; and the second electrode 01, the suspension electrode 02 and the touch-control electrode 03 may be disconnected from each other.

As shown in FIG. 1, by disposing the isolation columns 113 between adjacent pixel definition regions 011, the common electrode 112 of the display panel, that is, entire cathode, may be divided into three parts using the isolation columns 113. The three parts may include the cathode corresponding to the light-emitting region, the cathode corresponding to the isolation region, and the cathode corresponding to the touch-control region. For example, the cathode corresponding to the light-emitting region may be the second electrode 01 disposed on the light-emitting functional layer 111, and the second electrode 01 may be configured as the display electrode; the cathode corresponding to the isolation region may be the suspension electrode 02 covering the top surface of the isolation column 113; and the cathode corresponding to the touch-control region may be the touch-control electrode 03 covering the pixel definition layer 110 on the side of the isolation column 113 away from the pixel definition region 011.

In the existing technology, the TFE may be formed first, and then the touch-control structure may be disposed on the TFE. The touch-control structure may include the touch-control electrodes. Compared with the existing technology, in the disclosed embodiments, a part of the common electrode of the display panel may be configured as the touch-control electrodes. There is no need to dispose additional the touch-control electrodes after the TFE is formed, which may be beneficial for simplifying process.

Furthermore, in the existing technology, the TFE may be formed first, and then the touch-control structure may be disposed on the TFE. Entire cathode of the display panel may be configured as the display electrode, which may result in relatively large parasitic capacitance between the display electrode and the touch-control electrode, thereby forming relatively large mutual interference between the display signal and the touch-control signal. In embodiments of the present disclosure, the common electrode of the display panel, that is, entire cathode, may be divided into the second electrodes (that is, the display electrodes), the suspension electrodes and the touch-control electrodes. Since a part of the common electrode is configured as the touch-control electrodes of the display panel, there is no need to dispose an additional touch-control structure on the TFE after the TFE is formed, which may avoid the problem in the existing technology that relatively large parasitic capacitance formed between the display electrode and the touch-control electrode causes relatively large mutual interference between the display signal and the touch-control signal. Therefore, compared with the existing technology, in embodiments of the present disclosure, a part of the common electrode may be configured as the touch-control electrodes of the display panel, which may be beneficial for reducing the mutual interference between the display signal and the touch-control signal, thereby being beneficial for improving the product yield.

The display panel provided by embodiments of the present disclosure may divide the common electrode of the display panel into three parts by disposing isolation columns between adjacent pixel definition regions. Three parts may be respectively second electrodes (configured as display electrodes) disposed on a light-emitting functional layer, suspension electrodes covering the top surface of the isolation columns, and touch-control electrodes covering the pixel definition layer on the side of the isolation columns away from the pixel definition region. As a result, the common electrode of the display panel may be divided into display electrodes, suspension electrodes and touch-control electrodes that are disconnected from each other. Compared with the existing technology, the display panel provided by embodiments of the present disclosure may not need to dispose additional touch-control electrodes after the TFE is formed, which may be beneficial for simplifying process; and a part of the common electrode may be configured as touch-control electrodes of the display panel, which may be beneficial for reducing mutual interference between the display signal and the touch-control signal, thereby being beneficial for improving the product yield.

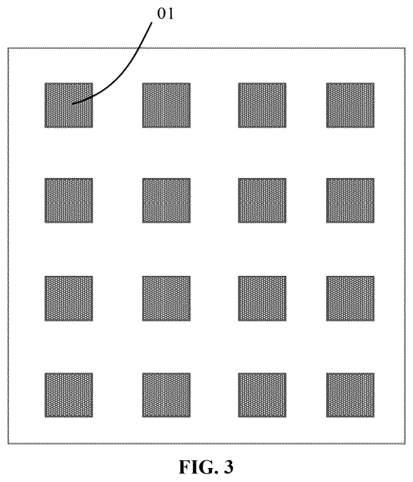

In some embodiments, FIG. 2 illustrates a top view of a display panel according to various embodiments of the present disclosure. FIG. 1 illustrates a cross-sectional view along an A-A′ direction in FIG. 2 according to various embodiments of the present disclosure. FIG. 1 may exemplarily illustrate two pixel definition regions 011, and the isolation columns 113 disposed by surrounding two pixel definition regions 011 respectively.

On the basis of FIG. 1, as shown in FIG. 2, the isolation column 113 may be set to surround the pixel definition region 011. The isolation column 113 surrounding the pixel definition region 011 refers to the first isolation column; the touch-control electrode 03 covering the pixel definition layer 110 between adjacent isolation columns 113 refers to the first touch-control electrode; and the suspension electrode 02 covering the top surface of the first isolation column 113 refers to the first suspension electrode.

For example, as shown in FIGS. 1-2, the isolation column may be configured to surround the pixel definition region 011 to form a closed loop shape, and one isolation column 113 under the suspension electrode 02 may be configured to be in one-to-one correspondence with one pixel definition region 011. FIG. 2 exemplarily shows 16 pixel definition regions 011 and 16 isolation columns 113 corresponding to 16 pixel definition regions 011, that is, the first isolation columns; and each isolation column 113 may be configured to surround the pixel definition region 011 to form a closed loop shape.

The cross-sectional view in FIG. 1 exemplarily illustrates two pixel definition regions 011, respectively located on the left and right sides of the touch-control electrode 03. The pixel definition region 011 located on the left side of the touch-control electrode 03 refers to the first pixel definition region, and the pixel definition region 011 located on the right side of the touch-control electrode 03 refers to the second pixel definition region. The isolation columns 113 disposed corresponding to the first pixel definition region may surround the first pixel definition region to form a closed loop shape; and the isolation columns 113 disposed corresponding to the second pixel definition region may surround the second pixel definition region to form a closed loop shape.

Therefore, by disposing the isolation columns 113 to surround the pixel definition regions 011, when the common electrode is evaporated on the display panel, the second electrodes 01 (that is, the display electrodes) corresponding to the pixel definition regions 011 may be separated from the common electrode 112 outside the isolation columns 113, thereby dividing the common electrode into three parts which may be the second electrodes 01 as shown in FIG. 2 (that is, the display electrode), the touch-control electrodes 03 and the suspension electrodes 02. In order to distinguish the isolation columns in the present disclosure, the isolation column 113 surrounding the pixel definition region 011 refers to the first isolation column. Therefore, the suspension electrode 02 covering the top surface of the first isolation column refers to the first suspension electrode, and the touch-control electrode 03 covering the pixel definition layer 110 between adjacent first isolation columns refers to the first touch-control electrode.

It should be noted that the second electrode 01, the touch-control electrode 03 and the suspension electrode 02 in FIG. 1 may be all formed of same cathode material. In FIG. 2, in order to distinguish the second electrode 01, the touch-control electrode 03 and the suspension electrode 02, the second electrode 01, the touch-control electrode 03 and the suspension electrode 02 shown in FIG. 2 may be respectively shown in different patterns.

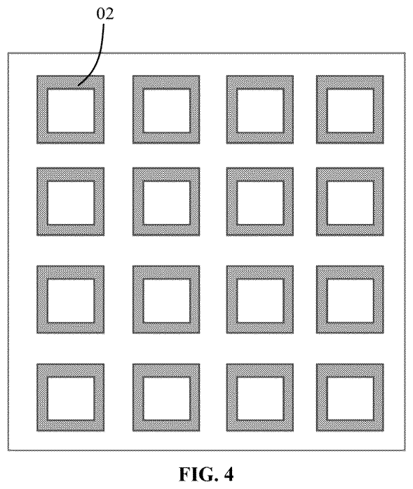

Exemplarily, FIG. 3 illustrates a top view only corresponding to second electrodes shown in FIG. 2 according to various embodiments of the present disclosure. Referring to FIGS. 2-3, the second electrodes 01 (that is, the display electrodes) may be distributed in an island shape using the sub-pixels corresponding to the pixel definition regions 011 as the smallest unit. The specific shape of the second electrode 01 may be determined by the sub-pixel. For example, the shape of the second electrode 01 may be a square, a rhombus, a circle, a triangle, a regular polygon, a star or the like, which may not be limited in embodiments of the present disclosure.

Exemplarily, FIG. 4 illustrates a top view only corresponding to suspension electrodes shown in FIG. 2 according to various embodiments of the present disclosure. Referring to FIGS. 2 and 4, the suspension electrode 02 may be formed above the isolation column 113 and surround the pixel definition region 011 to form a closed loop shape; and the closed loop shape formed by the suspension electrode 02 may be adjusted according to the sub-pixel shape.

Exemplarily, FIG. 5 illustrates a top view only corresponding touch-control electrodes shown in FIG. 2 according to various embodiments of the present disclosure. Referring to FIGS. 2 and 5, the touch-control electrode 03 may be formed between adjacent isolation columns 113; and the touch-control electrodes 03 formed within a touch-control unit may be connected with each other in a mesh structure. As shown in FIG. 5, the touch-control electrodes 03 formed between 16 isolation columns 113 may be regarded as a touch-control unit.

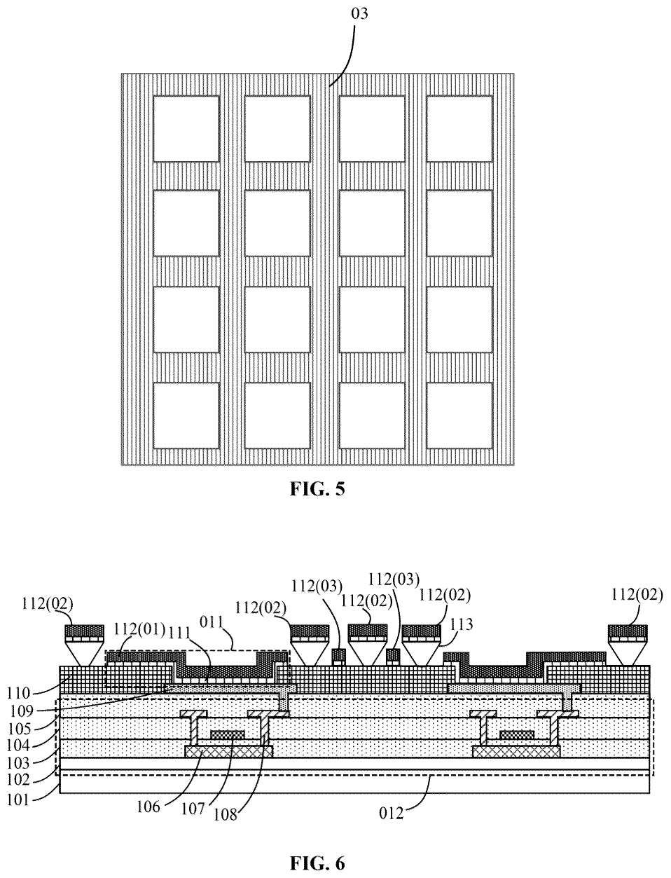

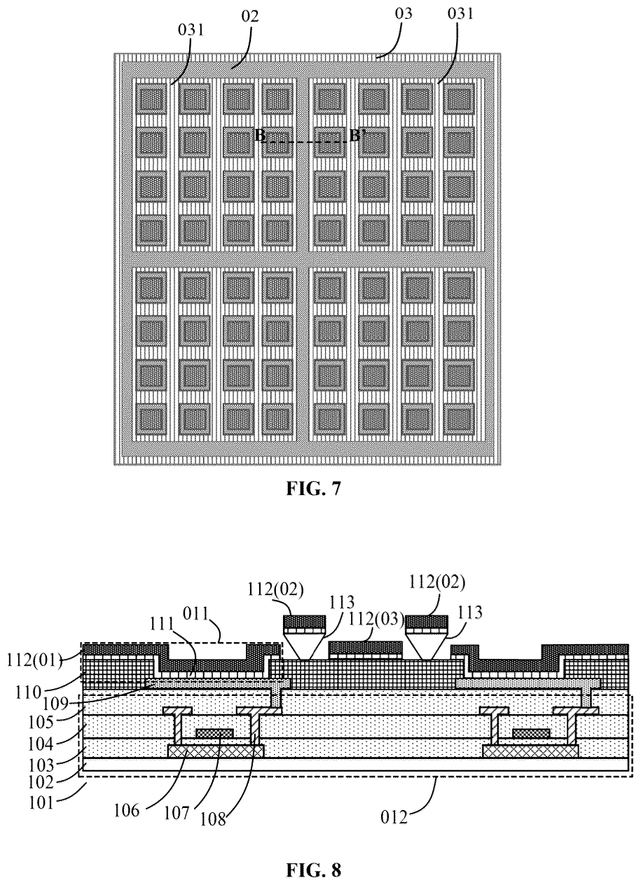

In some embodiments, FIG. 7 illustrates a top view of another display panel according to various embodiments of the present disclosure; and FIG. 6 illustrates a cross-sectional view along a B-B′ direction in FIG. 7 according to various embodiments of the present disclosure. As shown in FIGS. 6-7, the touch-control electrode 03 may be divided into a plurality of touch-control electrode blocks 031, that is, a plurality of touch-control units. For example, the touch-control electrode 03 formed between 16 isolation columns 113 in FIG. 6 may be regarded as a touch-control unit.

For example, referring to FIGS. 6-7, the isolation column 113 may be disposed to surround the touch-control electrode block 031; the isolation column 113 disposed to surround the touch-control electrode block 031 refers to the second isolation column; the second isolation column may be on the pixel definition layer 110 between adjacent touch-control electrode blocks 031; the suspension electrode 02 covering the top surface of the second isolation column refers to the second suspension electrode; and the second suspension electrode may be disconnected from the touch-control electrode block 031. In embodiments of the present disclosure, the second isolation column may be disposed between adjacent touch-control electrode blocks 031. The second isolation columns may divide the common electrode into the second suspension electrodes covering the top surface of the second isolation columns and the touch-control electrode blocks on two sides of the second isolation column to achieve electrode isolation between the touch-control electrode blocks 031. After the second isolation columns are disposed, each touch-control electrode block may be insulated and separated from each other. By providing the touch-control drive signal to each touch-control electrode block, the capacitance value corresponding to the touch-control electrode block at the user's touch-control position may change, such that the position of the touch-control electrode block corresponding to the change in capacitance value may be determined as the touch-control position.

It should be noted that only four touch-control electrode blocks 031 are illustrated in FIGS. 6-7; and exemplarily, the touch-control electrode 03 formed between 16 isolation columns 113 may be regarded as a touch-control electrode block 031, which may not be limited in embodiments of the present disclosure.

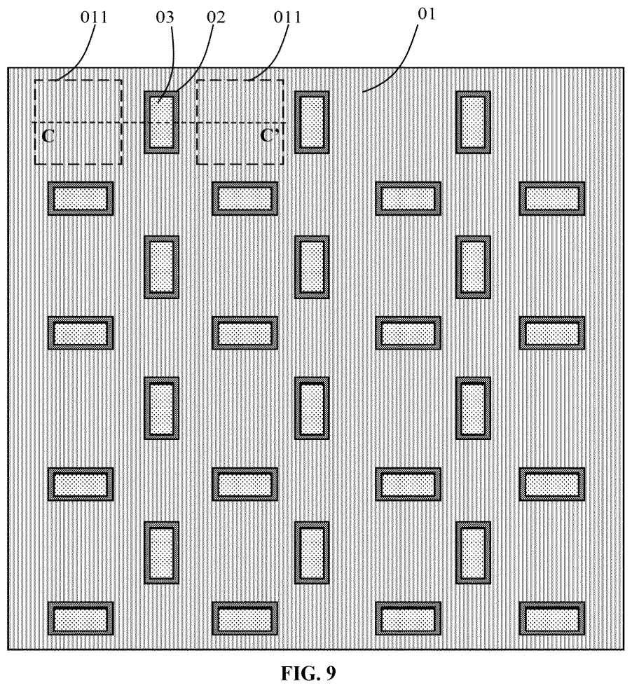

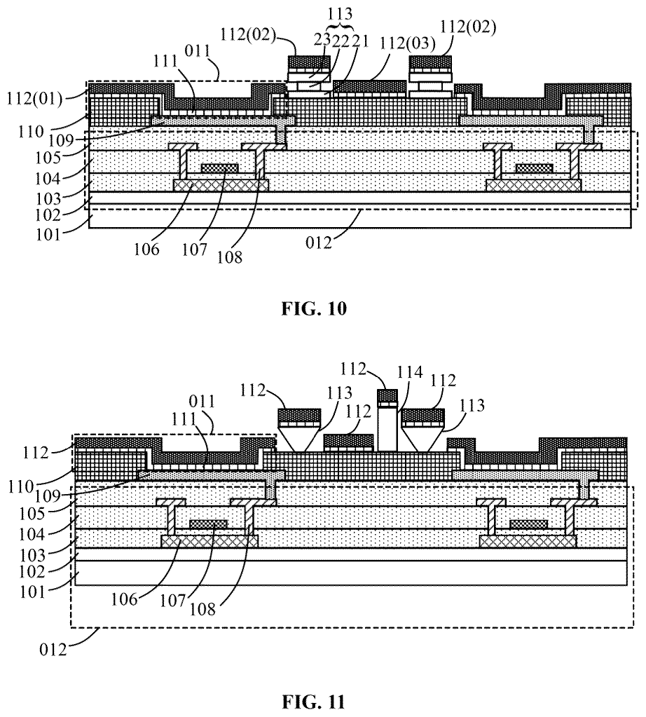

In some embodiments, FIG. 9 illustrates a top view of another display panel according to various embodiments of the present disclosure, and FIG. 8 illustrates a cross-sectional view along a C-C′ direction in FIG. 9 according to various embodiments of the present disclosure. As shown in FIGS. 8-9, the isolation column 113 may be disposed to surround the pixel definition layer 110 between adjacent pixel definitions 011. In order to be distinguished from the first isolation column and the second isolation column mentioned above, the isolation column 113 disposed to surround the pixel definition layer 110 between adjacent pixel definitions 011 refers to the third isolation column. The touch-control electrode 03 covered on the pixel definition layer 110 in the region surrounded by the third isolation column refers to the second touch-control electrode, and the suspension electrode 02 covering the top surface of the third isolation column refers to the third suspension electrode.

For example, on the basis of FIG. 8, as shown in FIG. 9, the isolation columns 113 may be disposed to surround the pixel definition layer 110 between adjacent pixel definition regions 011; that is, the isolation columns 113 may be disposed in the gaps between adjacent pixel definition regions 011. Therefore, the isolation columns 113, that is, the third isolation columns, may be disposed to surround the pixel definition layer 110 between adjacent pixel definition regions 011. When the common electrode is evaporated on the display panel, the common electrode may also be divided into three parts, which may be respectively the second electrodes 01 as shown in FIG. 9 (that is, the display electrodes), the touch-control electrodes 03 (that is, the second touch-control electrodes), and the suspension electrode 02 (that is, the third suspension electrodes).

The second touch-control electrode may be formed by the common electrode 112 on the pixel definition layer 110 in the region surrounded by the third isolation column; the third suspension electrode may be formed by the common electrode 112 covering the top surface of the third isolation column; and except for the second touch-control electrodes and the third suspension electrodes, remaining common electrode 112 may be configured as the second electrodes 01, that is, the display electrodes.

Therefore, by disposing the isolation columns 113 to surround the pixel definition layer 110 between adjacent pixel definition regions 011, the common electrode may also be divided into three parts. The common electrode 112 on the pixel definition layer 110 in the region surrounded by the third isolation column may be configured as the touch-control electrode 03. There may be no need to dispose additional touch-control electrodes 03, which may be beneficial for simplifying the process.

It should be noted that in FIG. 9, in order to distinguish the second electrode 01, the touch-control electrode 03 and the suspension electrode 02, the second electrode 01, the touch-control electrode 03 and the suspension electrode 02 shown in FIG. 9 may be respectively shown in different patterns.

In some embodiments, when the isolation column is formed, the projection of the bottom surface of the isolation column toward the pixel definition layer on the substrate may be configured to be within the projection of the top surface of the isolation columns away from the pixel definition layer on the substrate. In such way, the top region of the isolation column may be greater than the bottom region of the isolation column. Moreover, the isolation column may have certain height. When the common electrode 112 is prepared by evaporation on entire surface, the common electrode 112 of the display panel (that is, entire-surface cathode) may be disconnected at the boundary of the isolation column. That is, the cathode on the left and right sides of the isolation column may be disconnected from the cathode at the top of the isolation column to divide the common electrode 112 into three parts, for example, the second electrodes 01, the suspension electrodes 02 and the touch-control electrodes 03 illustrated in FIG. 1.

For example, as shown in FIG. 1, the shape of the isolation column 113 may be configured to an inverted trapezoid. The material forming the isolation column 113 may include an organic material and/or an inorganic material.

In some embodiments, when the isolation column is formed, the longitudinal cross-sectional size of the isolation column may first decrease and then increase along the direction away from the pixel definition layer. The isolation column may be configured in above-mentioned manner, and the isolation column may have certain height. When the common electrode 112 is prepared by evaporation on entire surface, the common electrode 112 of the display panel (that is, entire-surface cathode), may be disconnected at the boundary of the isolation column. That is, the cathode on the left and right sides of the isolation column may be disconnected from the cathode at the top of the isolation column to divide the common electrode 112 into three parts, for example, the second electrodes 01, the suspension electrodes 02 and the touch-control electrodes 03 illustrated in FIG. 1.

Exemplarily, FIG. 10 illustrates a film layer structural schematic of a display panel according to various embodiments of the present disclosure. As shown in FIG. 10, along the direction away from the pixel definition layer 110, the longitudinal cross-sectional size of the isolation column 113 may first decrease and then increase.

In some embodiments, as shown in FIG. 10, along the direction away from the substrate 101, the first film layer 21, the second film layer 22 and the third film layer 23 may be stacked with each other; and the first film layer 21, the second film layer 22 and the third film layer 23 may form the isolation columns 113. The dimensions of the longitudinal cross-sections of the first film layer 21 and the third film layer 23 along the horizontal direction may same; and the dimensions of the longitudinal cross-sections of the first film layer 21 and the third film layer 23 along the horizontal direction may be greater than the dimension of the longitudinal cross-section of the second film layer 22 along the horizontal direction. Therefore, the first film layer 21, the second film layer 22 and the third film layer 23 may form an I-shape, that is, the isolation column 113 may be configured to be an I-shape.

It should be noted that FIGS. 1 and 10 only exemplarily illustrate that the shapes of the isolation columns 113 are configured to be an inverted trapezoid and an I-shape respectively, which may not limit the shapes of the isolation columns. In some embodiments, the isolation columns may also be configured to be any other shapes to achieve dividing the common electrode of the display panel into three parts, which may not be limited in embodiments of the present disclosure.

In some embodiments, FIG. 11 illustrates another film layer structural schematic of a display panel according to various embodiments of the present disclosure. As shown in FIG. 11, the display panel may further include a support column 114; and one support column 114 may be exemplarily shown in FIG. 11.

The support column 114 may be disposed on the pixel definition layer 110 between adjacent pixel definition regions 011. The support column 114 may play a supporting role in the display panel. The height of the support column 114 may be greater than or equal to the height of the isolation column 113. With such configuration, the support columns 114 may play a supporting role in the display panel. The support column 114 may be configured to support the cover plate covering the light-emitting side of the display panel, which may prevent the cover plate from contacting the film layer of the display panel to scratch the display panel, and also support the cover plate when the display panel is pressed. For example, when the support column 114 is disposed on the pixel definition layer 110 between adjacent pixel definition regions 011, the common electrode 112 may also include an electrode covering the top of the support column 114. Similarly, the electrode covering the top of the isolation column 113 refers to the suspension electrode.

Therefore, the common electrode 112 on the display panel (that is, entire cathode) may be divided into four parts through the support columns 114 and the isolation columns 113, which may be respectively the second electrodes (that is, the display electrodes) corresponding to the pixel definition region 011, the touch-control electrodes covering the pixel definition layer 110 on the side of the isolation columns away from the pixel definition region 011, the suspension electrodes covering the top surface of the isolation columns, and the suspension electrodes covering the top surface of the support columns.

The support column 114 and the isolation column 113 may be made of a same material. For example, the support column 114 and the isolation column 113 may be made of a same inorganic metal material, such as titanium, aluminum or the like, or the support column 114 and the isolation column 113 may be made of a same organic film layer material, such as polyimide.

For example, when the support columns 114 and the isolation columns 113 are prepared on the pixel definition layer 110 using an exemplary half-tone mask process, since the support columns 114 and the isolation columns 113 are made of a same material, there is no need to repeat the process, which may be beneficial for simplifying the process and reducing manufacturing costs.

In some embodiments, as shown in FIG. 1, the isolation columns 113 and the pixel definition layer 110 may be made of different materials. For example, the pixel definition layer 110 may be made of the first material, and the isolation columns 113 may be made of the second material. For example, the first material may be deposited to prepare and form the pixel definition layer 110. After the pixel definition layer 110 is patterned to form the pixel definition regions 011, the second material may need to be deposited again to prepare the isolation columns 113 on the pixel definition layer 110 between the pixel definition regions 011, which may result in repeated process.

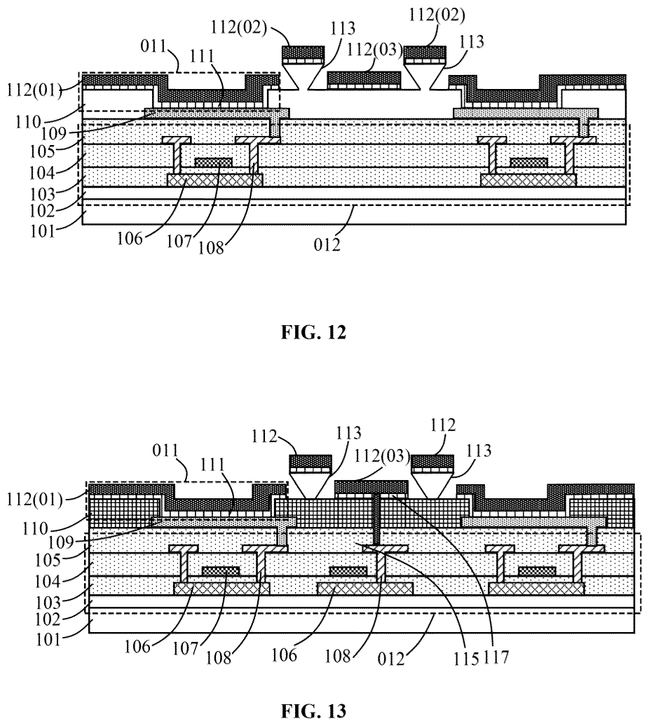

Based on above, in some embodiments, FIG. 12 illustrates another film layer structural schematic of a display panel according to various embodiments of the present disclosure. As shown in FIG. 12, when the isolation column 113 and the pixel definition layer 110 are made of a same material, the isolation column 113 and the pixel definition layer 110 may be formed into a single piece.

For example, when the isolation column 113 and the pixel definition layer 110 are made of a same material (for example, the isolation column 113 and the pixel definition layer 110 are both made of the first material or the second material), only one process may be needed. That is, the first material or the second material may be deposited to form a preparation layer; next, the preparation layer may be patterned to form the isolation column 113 and pixel definition layer 110 as shown in FIG. 12; subsequently, the pixel definition layer 110 may be patterned to form the pixel definition layer 110 having the pixel definition regions 011.

Therefore, when the isolation column 113 and the pixel definition layer 110 are made of a same material, there is no need to repeat the process, which may be beneficial for simplifying the process and further reducing the production cost.

In some embodiments, the display panel may further include touch-control wires. The touch-control wires may be formed using at least one metal layer in the driving circuit layer. An insulating layer between the touch-control wire and the touch-control electrode may be configured with the first vias, and the touch-control wire and the touch-control electrode may be electrically connected through the first vias. Touch-control wires may be configured to receive signals and transmit the signals to the touch-control electrodes.

Exemplarily, FIG. 13 illustrates another film layer structural schematic of a display panel according to various embodiments of the present disclosure. As shown in FIG. 13, the metal layer in the driving circuit layer 012 may include the semiconductor active layer 106, the gate metal layer 107 and the source and drain layer 108. The touch-control wires may be formed using the semiconductor active layer 106 and the source and drain layer 108 in the driving circuit layer 012. The touch-control wire formed using the semiconductor active layer 106 and the source and drain layer 108 may be electrically connected to the touch-control electrode 03 through the first via 115. The touch-control wire may also be formed only using the source and drain layer 108 in the driving circuit layer 012, and the touch-control wire formed using the source and drain layer 108 may be electrically connected to the touch-control electrode 02 through the first via.

In some embodiments, the touch-control wire may be formed using the semiconductor active layer 106 in the driving circuit layer. The touch-control wire formed in the semiconductor active layer 106 may be electrically connected to the touch-control electrode 03 through corresponding first via 115. In other embodiments, the touch-control wire may be formed using the gate metal layer 107 in the driving circuit layer. The touch-control wire formed using the gate metal layer 107 may be electrically connected to the touch-control electrode 03 through corresponding first via.

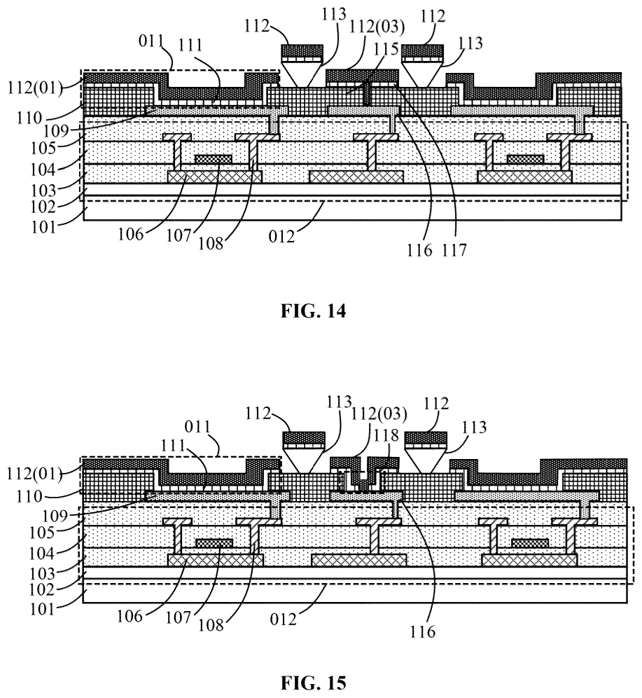

Exemplarily, FIG. 14 illustrates another film layer structural schematic of a display panel according to various embodiments of the present disclosure. As shown in FIG. 14, the touch-control wire may also be formed using the first electrode layer 116. The touch-control wire formed using the first electrode layer 116 may be electrically connected to the touch-control electrode 03 through the first via 115.

It should be noted that the first electrode layer 116 and the first electrode 109 may be made of a same material, for the sake of distinction, which may refer to the first electrode layer 116 herein.

In the existing technology, when the touch-control structure is disposed on TFE, the touch-control wires need to be routed across a blocking wall structure. During the exposure process, the photoresist may accumulate heavily at the bottom of the blocking wall structure. Therefore, it is difficult to effectively remove the photoresist by exposure and development, which may result in photoresist residue. As a result, when forming the touch-control wires, metal residue may be formed on two sides of the bottom of the blocking wall structure to causing short circuit, which may greatly affect product yield. Compared with the existing technology, in embodiments of the present disclosure, a part of the common electrode of the display panel may be configured as the touch-control electrodes, and the touch-control wires may be disposed in the driving circuit layer or the first electrode layer, that is, the touch-control wires may be disposed below the touch-control electrodes, which may solve the short circuit problem caused by that the touch-control wires may need to cross the blocking wall structure due to the touch-control structure disposed on the TFE in the existing technology, which may be beneficial for improving the product yield.

In the existing technology, the TFE may be formed first, and then the touch-control structure may be disposed on the TFE. Since the display panels of existing electronic products such as mobile phones are configured as curved screens, the touch-control wires on the TFE may be easily broken because the film layer on the TFE may be far from the neutral plane. Compared with the existing technology, in embodiment of the present disclosure, the touch-control wires may be disposed under the touch-control electrodes on the display panel, which may reduce the problem in the existing technology that the touch-control wires on the TFE are easily broken due to the film layer on the TFE being far away from the neutral plane.

In some embodiments, referring to FIG. 13 or 14, a suspended light-emitting functional layer 117 may be also disposed on the side of the touch-control electrode 03 facing the substrate 101; the suspended light-emitting functional layer 117 may be disconnected from the light-emitting functional layer 111 on the first electrode 109; and the suspended light-emitting functional layer 117 may be configured with a through hole, and the touch-control electrode 02 may be electrically connected to the touch-control wire through the through hole.

For example, the suspended light-emitting functional layer 117 may be made of a same material as the light-emitting functional layer 111 on the first electrode 109. When preparing the light-emitting functional layer 111 of the display panel, since the light-emitting functional layer material is deposited on entire surface, the light-emitting functional material may be formed on the side of the touch-control electrode 03 facing the substrate 101. Since the light-emitting functional material herein is not configured to emit light, the light-emitting functional material refers to the suspended light-emitting functional layer 117. In addition, since the suspended light-emitting functional layer 117 herein does not affect the function of the display panel, retaining the suspended light-emitting functional layer 117 herein may reduce corresponding process of removing the suspended light-emitting functional layer 117.

Similarly, the light-emitting functional material may be also formed on the isolation column 113. Since the light-emitting functional material formed on the isolation column 113 is not configured to emit light, the light-emitting functional material also refers to the suspended light-emitting functional layer. In addition, since the suspended light-emitting functional layer formed on the isolation column 113 does not affect the function of the touch-control display panel, the suspended light-emitting functional layer 117 on the isolation column 113 may also be retained accordingly, which may reduce corresponding process to removing the suspended light-emitting functional layer.

In some embodiments, as shown in FIG. 14, in order to improve the contact area between the touch-control electrode 03 and the touch-control wire formed using the first electrode layer 116, relatively large openings may be formed on the pixel definition layer 110 below the touch-control electrode 03.

Exemplarily, FIG. 15 illustrates another film layer structural schematic of a display panel according to various embodiments of the present disclosure. As shown in FIG. 15, a relatively large opening 118 may be formed on the pixel definition layer 110 below the touch-control electrode 03, which may improve the contact area between the touch-control electrode 03 and the touch-control wire, thereby being beneficial for improving product performance.

In some embodiments, as shown in any of FIGS. 13-15, during the operation of the display panel, the second electrode 01 may also need to receive signals. Therefore, the display panel may further include the second electrode wire for receiving and transmitting signals to the second electrode 01.

The second electrode wire may also be formed using at least one metal layer in the driving circuit layer 012; the insulating layer between the second electrode wire and the second electrode may be configured with the second via; and the second electrode wire and the second electrode may be electrically connected through the second via.

For example, the layout of the second electrode wires may be similar to the layout of the touch-control wires, that is, the second electrode wires and the touch-control wires may be all formed by at least one metal layer in the drive circuit layer 012. Therefore, the layout manner of the second electrode wires may not be described in detail herein, which may refer to the layout manner of the touch-control wires mentioned above.

The present disclosure also provides a display apparatus, including the display panel in any one of above-mentioned display panel embodiments. Therefore, the display apparatus may have the technical features of the display panel provided by embodiments of the present disclosure and may achieve the beneficial effects of the display panel provided by embodiments of the present disclosure. For similarities, reference may be made to above description of the display panel provided by embodiment of the present disclosure, which may not be described in detail herein.

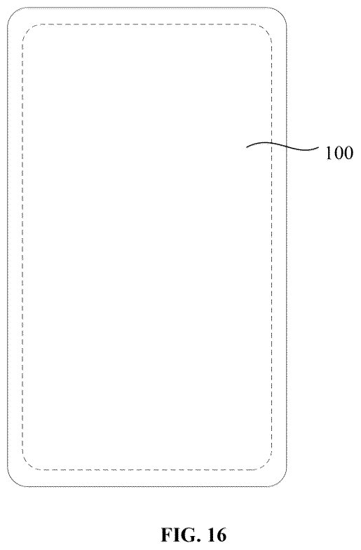

Exemplarily, FIG. 16 illustrates a structural schematic of a display apparatus according to various embodiments of the present disclosure. As shown in FIG. 16, the display apparatus provided by embodiments of the present disclosure may include the display panel 100 provided by any of above-mentioned embodiments of the present disclosure. In one embodiment provided in FIG. 16, a mobile phone may be taken as an example to illustrate the display apparatus. It can be understood that the display apparatus provided in embodiments of the present disclosure may be any electronic product with a display function, which may include, but may not be limited to, the following categories such as mobile phones, televisions, laptops, desktop monitors, tablets, digital cameras, smart bracelets, smart glasses, vehicle displays, medical equipment, industrial control equipment, touch-control interactive terminals and the like, which may not be limited in embodiments of the present disclosure.

The display apparatus provided by embodiments of the present disclosure may include above-mentioned display panel, which may also solve same technical problems as above-mentioned display panel embodiment and achieve same technical effect, which may not be described in detail herein.

Embodiments of the present disclosure also provide a formation method of a display panel, which may be configured to form the display panel described in above-mentioned embodiments.

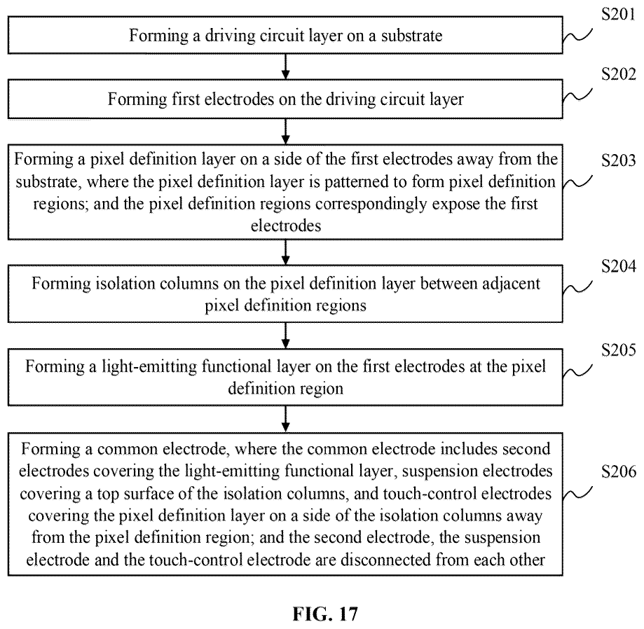

FIG. 17 illustrates a flowchart of a formation method of a display panel according to various embodiments of the present disclosure. As shown in FIG. 17, the formation method of the display panel may include the following exemplary steps.

At S201, the driving circuit layer may be formed on the substrate.

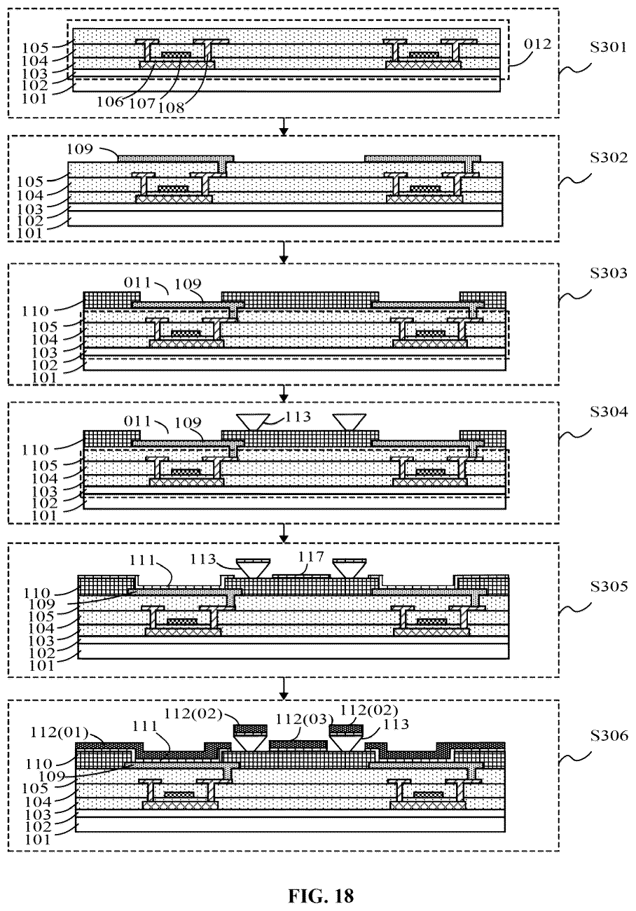

For example, FIG. 18 illustrates a schematic of a formation process of a display panel according to various embodiments of the present disclosure. As shown in S301 of FIG. 18, the substrate 101 may be provided, and the driving circuit layer 012 may be formed on the substrate 101.

Forming the driving circuit layer 012 on the substrate 101 is a well-known technical manner for those skilled in the art, which may not be described in detail herein.

The driving circuit layer 012 may include the buffer layer 102, the semiconductor active layer 106, the first insulating layer 103, the gate metal layer 107, the second insulating layer 104, the source and drain layer 108 and the third insulating layer 105. The semiconductor active layer 106 may be patterned to form a channel of a thin film transistor. The gate metal layer 107 may be patterned to form the gate electrode of the thin film transistor and the scan lines of the driving circuit. The source and drain layer 108 may be patterned to form the source electrode and the drain electrode of the thin film transistor and the data lines and power lines of the driving circuit. The third insulating layer 105 may cover the second insulating layer 104 and the source and drain layer 108, which may be configured to planarize the driving circuit layer 012 and provide a flat base for the preparation of the first electrode 109.

At S202, the first electrode may be formed on the driving circuit layer.

For example, as shown in S302 of FIG. 18, the first electrode 109 as shown in the FIG. 18 may be formed on the driving circuit layer 012 by exemplary exposure and development manner.

At S203, the pixel definition layer may be formed on the first electrode; the pixel definition layer may be patterned to form the pixel definition region; and the pixel definition region may correspondingly expose the first electrode.

For example, as shown in S303 of FIG. 18, one pixel definition layer 110 may be covered on the first electrode 109, and the pixel definition layer 110 may be subsequently patterned to form the pixel definition region 011.

The pixel definition region 011 may correspondingly expose the first electrode 109 to achieve electrical connection between the first electrode 109 and the light-emitting functional layer 111 described below.

At S204, the isolation column may be formed on the pixel definition layer between adjacent pixel definition regions.

For example, as shown in S304 of FIG. 18, the isolation column 113 may formed on the pixel definition layer 110 and between adjacent pixel definition regions 011.

For example, the shape of the isolation column 113 may be an inverted trapezoid, an I-shape, or the like, which may not be limited in embodiments of the present disclosure.

At S205, the light-emitting functional layer may be formed on the first electrode at the pixel definition region.

For example, as shown in S305 of FIG. 18, the light-emitting functional layer 111 may be formed on the first electrode 109. When the light-emitting functional layer 111 is formed on the first electrode 109, entire surface may be covered with the light-emitting functional material. Therefore, while the light-emitting functional layer 111 is formed on the first electrode 109 of the pixel definition region 011, a same light-emitting functional material may be also cover the pixel definition layer 110 between adjacent pixel definition regions 011. The light-emitting functional material covering the pixel definition layer 110 between adjacent pixel definition regions 011 refers to the suspended light-emitting functional layer 117.

Since the isolation column 113 is formed on the pixel definition layer 110 between adjacent pixel definition regions 011, when entire surface is covered with the light-emitting functional material, the isolation column 113 may disconnect the suspended light-emitting functional layer 117 from the light-emitting functional layer 111 on the first electrode 109.

It should be noted that while the light-emitting functional layer 111 is formed on the first electrode 109 of the pixel definition region 011, the top of the isolation column 113 may be also covered with the light-emitting functional material; and the light-emitting functional material covering the top of the isolation column 113 also refers to the suspended light-emitting functional layer. For example, as shown in S305 of FIG. 18, due to the existence of the isolation columns 113, when entire surface is covered with thee light-emitting functional material to form the light-emitting layer, the light-emitting layer may be divided into three parts, which may be respectively the light-emitting functional layer 111 formed corresponding to the first electrodes 109, the suspended light-emitting functional layer 117 formed on the pixel definition layer 110 between the pixel definition regions 011, and the light-emitting layer covering the top of the isolation columns 113.

At S206, thee common electrode may be formed. The common electrode may include the second electrode covering the light-emitting functional layer, the suspension electrode covering the top surface of the isolation column, and the touch-control electrode covering the pixel definition layer on the side of the isolation column away from the pixel definition region. The second electrode, the suspension electrode and the touch-control electrode may be disconnected from each other.

For example, as shown in S306 of FIG. 18, entire surface may be covered by the cathode material to form the common electrode 112; and the common electrode 112 may be divided into three parts through the isolation columns 113, which may be respectively the second electrodes 01 covering the light-emitting functional layer 111, the suspension electrodes 02 covering the top surface of the isolation columns 113, and the touch-control electrodes 03 covering the pixel definition layer 110 on the side of the isolation columns 113 away from the pixel definition region 011.

Therefore, by disposing the isolation columns 113, the second electrodes 01, the suspension electrodes 02 and the touch-control electrodes 03 which are disconnected from each other may be formed.

In some embodiments, forming the isolation column on the pixel definition layer between adjacent pixel definition regions may include using a half-tone mask process to form the support column and the isolation column on the pixel definition layer between adjacent pixel definition regions, where the height of the support column may be greater than or equal to the height of the isolation column.

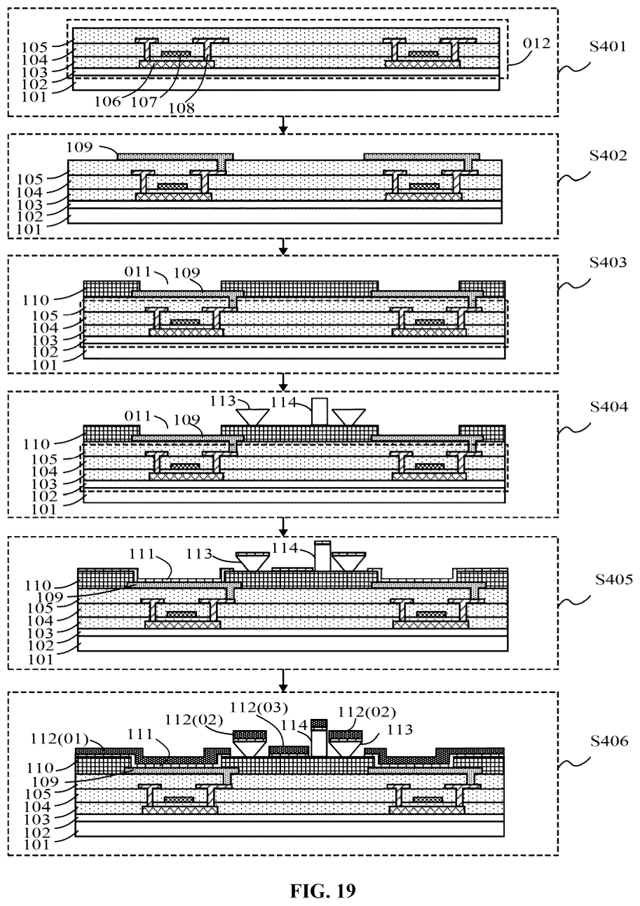

For example, FIG. 19 illustrates another schematic of a formation process of a display panel according to various embodiments of the present disclosure. As shown in S404 of FIG. 19, while the isolation column 113 is formed on the pixel definition layer 110 between adjacent pixel definition regions 011, the support column 114 may also be formed. The support column 114 may be configured to support the display panel.

The half-tone mask process may use a half-tone mask (HTM). HTM is a mask using a film with a certain optical transmittance to achieve partial light transmission. As an advanced mask material, HTM is mainly used in the production of thin film transistor (TFT) panels. During usage, conventional masks only have two effects including light transmission and opacity for the light of a specific wavelength. The half-tone mask (HTM) may be formed by sputtering and depositing multiple times on a glass substrate to form two layers including a semi-permeable film and a light-blocking film, and then two photolithography processes may be configured to form pattern structures including fully transparent, fully opaque, and partially transparent effects. All indicators of graphic accuracy of the half-tone mask may be higher than indicators of conventional masks.

Therefore, by utilizing the graphic structure of the half-tone mask that can partially transmit light, when the isolation column 113 and the support column 114 are formed on the pixel definition layer 110 between adjacent pixel definition regions 011, the isolation columns 113 and the support columns 114 may be formed simultaneously using single exposure process.

When the conventional mask is used, the conventional mask may only have two effects of light transmission and opacity for the light of a specific wavelength. Therefore, one exposure process may be needed when the isolation column 113 is formed, and another exposure process may be also needed when the support column 114 is formed. Compared with using the conventional mask, in embodiments of the present disclosure, the half-tone mask may be configured to simultaneously form the isolation column 113 and the support column 114 using only one exposure process.

In some implementation manners, other technical manners well known to those skilled in the art may also be configured to form the support columns and the isolation columns on the pixel definition layer between adjacent pixel definition regions, which may not be limited in embodiments of the present disclosure.

As shown in S404 of FIG. 19, while forming the isolation columns 113 on the pixel definition layer 110 between adjacent pixel definition regions 011, the support columns 114 may be formed simultaneously. As a result, when entire surface is covered with the light-emitting functional material and the cathode material in subsequent steps, the light-emitting functional material (referring to the light-emitting layer (shown as S405 in FIG. 19)) and the common electrode (shown as S406 in FIG. 19) may be sequentially formed above the support columns 114.

In addition, due to the existence of the support columns 114, the common electrode 112 shown in S406 of FIG. 19 may be divided into four parts disconnected from each other, which may be respectively the second electrodes 01 covering the light-emitting functional layer 111, the suspension electrodes 02 covering the top surface of the isolation columns 113, the common electrode (referring to the suspension electrode) covering the top surface of the support columns 114, and the touch-control electrode 03 covering the pixel definition layer 110 on the side of the isolation columns 113 away from the pixel definition region 011.

It should be noted that S401 in FIG. 19 may be same as S301 in FIG. 18, S402 in FIG. 19 may be same as S302 in FIGS. 18, and S403 in FIG. 19 may be same as S303 in FIG. 18. For S404 in FIG. 19, the support columns 114 may be formed while forming the isolation columns 113 on the pixel definition layer 110 between adjacent pixel definition regions 011. For S304 in FIG. 18, only the isolation columns 113 may be formed on the pixel definition layer 110 between adjacent pixel definition regions 011.

In some embodiments, before forming the common electrode, the method may include forming the through hole on the suspended light-emitting functional layer through a laser drilling process.

For example, as shown in any of FIGS. 13-15, before forming the common electrode 112, the through hole may be formed on the suspended light-emitting functional layer 117. When the touch-control electrode 03 is formed by covering the cathode material, the touch-control electrode 03 and the touch-control wire may be electrically connected to each other.

In some embodiments, other technical manners well known to those skilled in the art may also be configured to form the through hole on the suspended light-emitting functional layer, which may not be limited in embodiments of the present disclosure.

It may be seen from above-mentioned embodiments that the present disclosure may at least achieve following beneficial effects.

The display panel provided in embodiments of the present disclosure may include the substrate; the driving circuit layer on the substrate; the first electrodes on the driving circuit layer; the pixel definition layer on the side of the first electrodes away from the substrate, where the pixel definition layer is patterned to form pixel definition regions, and the pixel definition regions correspondingly expose the first electrodes; the light-emitting functional layer formed on the first electrodes at the pixel definition regions; the isolation columns on the pixel definition layer between adjacent pixel definition regions; and the common electrode. The common electrode may include the second electrodes covering the light-emitting functional layer, the suspension electrodes covering a top surface of the isolation columns, and the touch-control electrodes covering the pixel definition layer on the side of the isolation columns away from the pixel definition region; and the second electrodes, the suspension electrodes and the touch-control electrodes may be disconnected from each other. As a result, by disposing the isolation columns between adjacent pixel definition regions, the common electrode of the display panel may be divided into display electrodes, suspension electrodes and touch-control electrodes that are disconnected from each other. Compared with the existing technology, the display panel provided by embodiments of the present disclosure may not need to dispose additional touch-control electrodes after the TFE is formed, which may be beneficial for simplifying process; and a part of the common electrode may be configured as touch-control electrodes of the display panel, which may be beneficial for reducing mutual interference between the display signal and the touch-control signal, thereby being beneficial for improving the product yield.

It should be noted that in the present disclosure, relational terms such as “first” and “second” may be only configured to distinguish one entity or operation from another entity or operation and may not necessarily require or imply that such actual relationship or order is between these entities or operations. Furthermore, the term “comprise”, “include” or any other variation thereof may be intended to cover a non-exclusive inclusion. Therefore, a process, a method, an article or apparatus including a set of elements may include not only those elements, but also other elements not expressly listed, or also include elements inherent in the process, the method, the article or apparatus. Without further limitations, an element defined by the statement “include . . . ” may not exclude the presence of additional identical elements in the process, the method, the article, or apparatus including such element.

The above may be merely embodiments of the present disclosure, which may make those skilled in the art to understand or implement the present disclosure. Various modifications to embodiments of the present disclosure may be apparent to those skilled in the art. General principles defined in the present disclosure may be implemented in other embodiments without departing from the spirit or scope of the present disclosure. Therefore, the present disclosure may not be limited to embodiments described in the present disclosure but may be accorded the widest scope consistent with the principles and novel features of the present disclosure.

What is claimed is:

1. A display panel, comprising:
a substrate;
a driving circuit layer on the substrate;
first electrodes on the driving circuit layer;
a pixel definition layer on a side of the first electrodes away from the substrate, wherein the pixel definition layer is patterned to form pixel definition regions; and the pixel definition regions correspondingly expose the first electrodes;
a light-emitting functional layer formed on the first electrodes at the pixel definition regions;
isolation columns on the pixel definition layer between adjacent pixel definition regions; and
a common electrode, wherein the common electrode includes second electrodes covering the light-emitting functional layer, suspension electrodes covering a top surface of the isolation columns, and touch-control electrodes covering the pixel definition layer on a side of the isolation columns away from the pixel definition region; and the second electrodes, the suspension electrodes and the touch-control electrodes are disconnected from each other.

2. The display panel according to claim 1, wherein:
the isolation columns include a first isolation column; the first isolation column is configured to surround a pixel definition region; the touch-control electrodes include a first touch-control electrode covering the pixel definition layer between adjacent isolation columns; and the suspension electrodes include a first suspension electrode covering a top surface of the first isolation column.

3. The display panel according to claim 2, wherein:
the first touch-control electrode includes a plurality of touch-control electrode blocks; and
the isolation columns further include a second isolation column; the second isolation column is on the pixel definition layer between adjacent touch-control electrode blocks; the second isolation column is configured to surround a touch-control electrode block; the common electrode further includes a second suspension electrode covering a top surface of the second isolation column; and the second suspension electrode and the touch-control electrode block are disconnected from each other.

4. The display panel according to claim 1, wherein:
the isolation columns include a third isolation column; the third isolation column is configured to surround the pixel definition layer between adjacent pixel definition regions; the touch-control electrodes include a second touch-control electrode; the second touch electrode covers the pixel definition layer in a region surrounded by the third isolation column; and the suspension electrodes includes a third suspension electrode covering a top surface of the third isolation column.

5. The display panel according to claim 1, wherein:
a projection of a bottom surface of an isolation column toward the pixel definition layer on the substrate is within a projection of a top surface of the isolation column away from the pixel definition layer on the substrate.

6. The display panel according to claim 1, wherein:
along a direction away from the pixel definition layer, a horizontal cross-sectional dimension of an isolation column decreases first and then increases.

7. The display panel according to claim 6, wherein:
the isolation column includes a first film layer, a second film layer and a third film layer stacked with each other along a direction away from the substrate; and
the first film layer, the second film layer and the third film layer form an I-shape.

8. The display panel according to claim 1, further including:
a support column disposed on the pixel definition layer between adjacent pixel definition regions, wherein a height of the support column is greater than or equal to a height of an isolation column.

9. The display panel according to claim 8, wherein:
the support column and the isolation column are made of a same material.

10. The display panel according to claim 8, wherein:
the isolation column is reused as the support column.

11. The display panel according to claim 1, wherein:
the isolation columns and the pixel definition layer are made of a same material.

12. The display panel according to claim 1, further including:
a touch-control wire, formed using at least one metal layer in the driving circuit layer, wherein a first via is formed at an insulating layer between the touch-control wire and a touch-control electrode; and the touch-control wire and the touch-control electrode are electrically connected to each other through the first via.

13. The display panel according to claim 12, wherein:
a suspended light-emitting functional layer is further disposed on a side of the touch-control electrode facing the substrate; and the suspended light-emitting functional layer is disconnected from the light-emitting functional layer on the first electrode; and
a through hole is formed at the suspended light-emitting functional layer, and the touch-control electrode is electrically connected to the touch-control wire through the through hole.

14. The display panel according to claim 1, further including:
a second electrode wire, formed using at least one metal layer in the driving circuit layer, wherein a second via is formed at an insulating layer between the second electrode wire and a second electrode; and the second electrode wire is electrically connected to the second electrode through the second via.

15. A display apparatus, comprising:
a display panel, comprising:
a substrate;
a driving circuit layer on the substrate;
first electrodes on the driving circuit layer;
a pixel definition layer on a side of the first electrodes away from the substrate, wherein the pixel definition layer is patterned to form pixel definition regions; and the pixel definition regions correspondingly expose the first electrodes;
a light-emitting functional layer formed on the first electrodes at the pixel definition regions;
isolation columns on the pixel definition layer between adjacent pixel definition regions; and
a common electrode, wherein the common electrode includes second electrodes covering the light-emitting functional layer, suspension electrodes covering a top surface of the isolation columns, and touch-control electrodes covering the pixel definition layer on a side of the isolation columns away from the pixel definition region; and the second electrodes, the suspension electrodes and the touch-control electrodes are disconnected from each other.

16. A formation method of a display panel, comprising:
forming a driving circuit layer on a substrate;
forming first electrodes on the driving circuit layer;
forming a pixel definition layer on a side of the first electrodes away from the substrate, wherein the pixel definition layer is patterned to form pixel definition regions; and the pixel definition regions correspondingly expose the first electrodes;
forming isolation columns on the pixel definition layer between adjacent pixel definition regions;
forming a light-emitting functional layer on the first electrodes at the pixel definition region; and
forming a common electrode, wherein the common electrode includes second electrodes covering the light-emitting functional layer, suspension electrodes covering a top surface of the isolation columns, and touch-control electrodes covering the pixel definition layer on a side of the isolation columns away from the pixel definition region; and the second electrode, the suspension electrode and the touch-control electrode are disconnected from each other.

17. The formation method according to claim 16, wherein forming the isolation columns on the pixel definition layer between adjacent pixel definition regions includes:
using a half-tone mask process to form support columns and the isolation columns on the pixel definition layer between adjacent pixel definition regions, wherein a height of a support column is greater than or equal to a height of an isolation column.

18. The formation method according to claim 16, wherein:
when forming the light-emitting functional layer on the first electrodes at the pixel definition region, the method further includes forming a suspended light-emitting functional layer on the pixel definition layer between adjacent pixel definition regions, wherein the isolation columns disconnect the suspended light-emitting functional layer from the light-emitting functional layer on the first electrodes; and
before forming the common electrode, the method further includes forming a through hole on the suspended light-emitting functional layer through a laser drilling process.
